(19) United States
(12) Patent Application Publication
(10) Pub. No.: US 2026/0030420 A1
(43) Pub. Date: Jan. 29, 2026

(54) Managing Hydrocarbon Wells Based on an Information System

(71) Applicant: EOG Resources, Inc., Houston, TX (US)

(72) Inventors: Michael Jiale Yang, Houston, TX (US); Pratik Kharel, Houston, TX (US)

(21) Appl. No.: 18/783,952

(22) Filed: Jul. 25, 2024

(51) Int. Cl. G06F 30/28

(52) U.S. Cl. CPC G06F 30/28

(57) ABSTRACT

Methods and systems for managing hydrocarbon wells are disclosed. The method includes measuring, via one or more hydrocarbon sensors, an amount of oil and an amount of natural gas produced from one or more hydrocarbon wells. The method additionally includes predicting whether the one or more hydrocarbon wells will likely produce an excess of natural gas. The method further includes in response to anticipating that the one or more hydrocarbon wells will likely produce the excess of natural gas, determining a selection of at least one hydrocarbon well that could be shut in or choked to eliminate the anticipated excess.

### BACKGROUND

Hydrocarbon well management is used in oil and gas operations such as drilling, well workover and well completion for maintaining the hydrostatic pressure and formation pressure to prevent the influx of formation fluids into the wellbore. Hydrocarbon well management involves the estimation of formation fluid pressures, the strength of the subsurface formations and the use of casing and mud density to offset those pressures in a predictable fashion. Understanding pressure and pressure relationships is important in hydrocarbon well management.

Hydrocarbon well management includes managing excess gas. In hydrocarbon well systems, it is common to have extra gas that needs to be removed. The traditional removal approach is flaring. Gas flaring allows operators to de-pressurize their equipment and manage unpredictable and large pressure variations by burning any excess gas. A more environmentally friendly alternative is CLGC, or Closed Loop Gas Capture, in which the gas is stored in a well and the well is permanently shut down.

### BRIEF DESCRIPTION OF THE DRAWINGS

FIG. 1 illustrates a flow diagram for hydrocarbon well management, in accordance with some embodiments of the present disclosure;

FIG. 2 illustrates a compressor summary page, in accordance with some embodiments of the present disclosure;

FIGS. 3A-3B illustrate a process to use custom groups, in accordance with some embodiments of the present disclosure;

FIG. 4 illustrates a well summary table, in accordance with some embodiments of the present disclosure;

FIG. 5 illustrates well information 500, in accordance with some embodiments of the present disclosure;

FIG. 6 illustrates a display of the X-day average of shut-in data 430, in accordance with some embodiments of the present disclosure;

FIG. 7 illustrates a display of the well capacity 440, in accordance with some embodiments of the present disclosure;

FIG. 8 illustrates a display of well details, in accordance with some embodiments of the present disclosure;

FIG. 9 illustrates a control room input piece, in accordance with some embodiments of the present disclosure;

FIG. 10 illustrates a display of summary metrics, in accordance with some embodiments of the present disclosure;

FIG. 11 illustrates an ESD monitoring page, in accordance with some embodiments of the present disclosure;

FIG. 12 illustrates a capacity remaining graph, in accordance with some embodiments of the present disclosure;

FIG. 13 illustrates a method for managing hydrocarbon wells, in accordance with some embodiments of the present disclosure.

While embodiments of this disclosure have been depicted and described and are defined by reference to exemplary embodiments of the disclosure, such references do not imply a limitation on the disclosure, and no such limitation is to be inferred. The subject matter disclosed is capable of considerable modification, alteration, and equivalents in form and function, as will occur to those skilled in the pertinent art and having the benefit of this disclosure. The depicted and described embodiments of this disclosure are examples only, and not exhaustive of the scope of the disclosure.

### DETAILED DESCRIPTION

For the purposes of this disclosure, computer-readable media may include any instrumentality or aggregation of instrumentalities that may retain data and/or instructions for a period of time. Computer-readable media may include, for example, without limitation, storage media such as a direct access storage device (e.g., a hard disk drive or floppy disk drive), a sequential access storage device (e.g., a tape disk drive), compact disk, CD-ROM, DVD, RAM, ROM, electrically erasable programmable read-only memory (EEPROM), and/or flash memory; as well as communications media such as wires, optical fibers, microwaves, radio waves, and other electromagnetic and/or optical carriers; and/or any combination of the foregoing.

Illustrative embodiments of the present invention are described in detail herein. In the interest of clarity, not all features of an actual implementation may be described in this specification. It will of course be appreciated that in the development of any such actual embodiment, numerous implementation-specific decisions may be made to achieve the specific implementation goals, which may vary from one implementation to another. Moreover, it will be appreciated that such a development effort might be complex and time-consuming, but would nevertheless be a routine undertaking for those of ordinary skill in the art having the benefit of the present disclosure.

To facilitate a better understanding of the present invention, the following examples of certain embodiments are given. In no way should the following examples be read to limit, or define, the scope of the invention. Embodiments of the present disclosure may be applicable to horizontal, vertical, deviated, or otherwise nonlinear wellbores in any type of subterranean formation. Embodiments may be applicable to injection wells as well as production wells, including hydrocarbon wells. Embodiments may be implemented using a tool that is made suitable for testing, retrieval and sampling along sections of the formation. Embodiments may be implemented with tools that, for example, may be conveyed through a flow passage in tubular string or using a wireline, slickline, coiled tubing, downhole robot or the like. Devices and methods in accordance with certain embodiments may be used in one or more of wireline, measurement-while-drilling (MWD) and logging-while-drilling (LWD) operations. “Measurement-while-drilling” is the term generally used for measuring conditions downhole concerning the movement and location of the drilling assembly while the drilling continues. “Logging-while-drilling” is the term generally used for similar techniques that concentrate more on formation parameter measurement.

The terms “couple” or “couples,” as used herein are intended to mean either an indirect or direct connection. Thus, if a first device couples to a second device, that connection may be through a direct connection, or through an indirect electrical connection via other devices and connections. Similarly, the term “communicatively coupled” as used herein is intended to mean either a direct or an indirect communication connection. Such connection may be a wired or wireless connection such as, for example, Ethernet or LAN. Such wired and wireless connections are well known to those of ordinary skill in the art and will therefore not be discussed in detail herein. Thus, if a first device communicatively couples to a second device, that connection may be through a direct connection, or through an indirect communication connection via other devices and connections.

### Overview

The present disclosure includes methods, systems, and software to perform hydrocarbon well management. According to an embodiment, a system for managing the production of oil and gas from a plurality of hydrocarbon wells may include one or more hydrocarbon sensors coupled to one or more hydrocarbon wells. The one or more hydrocarbon sensors may be operable to measure an amount of oil and an amount of natural gas produced from the one or more hydrocarbon wells. The system may also include an information handling system in electronic communication with the one or more hydrocarbon sensors. The information handling system may include a processor and a non-transitory computer readable medium for storing one or more instructions that, when executed, causes the processor to perform operations. The operations may include predicting whether the one or more hydrocarbon wells will likely produce an excess of natural gas. The operations may further include, in response to anticipating that the one or more hydrocarbon wells will likely produce the excess of natural gas, determining a selection of at least one hydrocarbon well that could be shut in or choked to eliminate the anticipated excess of natural gas being produced.

In particular embodiments, the selection may be determined at least in part to minimize a reduction of oil produced as a result of shutting in or choking at least one hydrocarbon well. In an embodiment, at least one of: each of the selected at least one hydrocarbon wells has a higher gas/oil ratio than each of the one or more hydrocarbon wells that were not selected, each of the selected at least one hydrocarbon wells is nearer a sales point than each of the one or more hydrocarbon wells that were not selected, or each of the selected at least one hydrocarbon wells is equipped with compression equipment.

In particular embodiments, the operations may include determining if the excess of natural gas being produced has been eliminated. The operations may further include, in response to determining that the excess of natural gas being produced has been eliminated, determining a second selection of at least one shut-in or choked hydrocarbon well that could be reopened without causing a second excess of natural gas. The second selection may be determined at least in part to maximize the amount of oil produced by the one or more hydrocarbon wells without causing the second excess of natural gas.

In particular embodiments, the operations may include determining an amount of natural gas each hydrocarbon well can temporarily hold based at least in part on one or more of tubing dimensions, casing dimensions, injection rates, and well pressure. Each of the shut-in or choked hydrocarbon wells selected to be reopened may have a lower gas/oil ratio than each of the shut-in or choked hydrocarbon wells that were not selected to be reopened.

In particular embodiments, the operations may include displaying a user interface. The user interface may be operable to allow a user to modify the selection.

In particular embodiments, the operations may include receiving production data from the one or more hydrocarbon sensors and determining a gas/oil ratio of at least one of the one or more hydrocarbon wells based on the production data of the at least one hydrocarbon well on days that the at least one hydrocarbon well did not have downtime.

In particular embodiments, the selection may be determined based at least in part on one or more of gas/oil ratio, boosting status, auto-choke status, and whether a user has designated wells to be unaltered. In particular embodiments, the selection may be updated at least daily.

In particular embodiments, the system for managing hydrocarbon wells may additionally include a logic controller operable to shut in at least one hydrocarbon well. The logic controller may be in electronic communication with the information handling system. In an embodiment, the operations may include communicating with the logic controller and to thereby shut in the selected at least one hydrocarbon well.

In particular embodiments, the system for managing hydrocarbon wells may additionally include at least one gas lift injection valve fluidly coupled to at least one of the one or more hydrocarbon wells. The at least one gas lift injection valve may be operable to perform at least one of injecting natural gas through tubing into a casing side of at least one of the one or more hydrocarbon wells or injecting natural gas through a casing side of at least one of the one or more hydrocarbon wells into tubing. In an embodiment, the operations may include determining if a hydrocarbon well undergoing injection is near full capacity.

According to another embodiment, a method for managing the production of oil and gas from a plurality of hydrocarbon wells may include measuring, via one or more hydrocarbon sensors, an amount of oil and an amount of natural gas produced from one or more hydrocarbon wells. The method may also include predicting whether the one or more hydrocarbon wells will likely produce an excess of natural gas. The method may further include, in response to anticipating that the one or more hydrocarbon wells will likely produce the excess of natural gas, determining a selection of at least one hydrocarbon well that could be shut in or choked to eliminate the anticipated excess of natural gas.

Technical advantages of certain embodiments of this disclosure may include one or more of the following. The systems and methods described herein may provide allocated production values based on days the well did not have downtime to get metrics for gas/oil ratio (GOR). The systems and methods described herein may perform calculations based on tubing/casing dimensions and current pressures and injection which are used to determine the amount of gas each well can temporarily hold. The systems and methods described herein may utilize a backend process to continually monitor the capacity of each well and shut off injection when capacity has been reached. The systems and methods described herein may provide a control room with a variety of functions. The control room may enable a user to create custom lists of oil wells by area or gathering systems. The custom lists of wells may be dynamically updated daily based on GOR values and other metrics. The control room may also enable the user to input a certain rate to remove from the system and recommend a list of wells with projected shut-in values. The control room may further enable the user to remotely shut in the wells through a click of a button. The control room may have access to all wells that were shut in and recommend the optimal wells to open back up to maximize oil production while minimizing gas production.

Other technical advantages will be readily apparent to one skilled in the art from the following figures, descriptions, and claims. Moreover, while specific advantages have been enumerated above, various embodiments may include all, some, or none of the enumerated advantages.

### Example Embodiments

Different from conventional CLGC, hydrocarbon well management may include temporarily shutting in wells and continuing to inject gas into the shut-in well's wellbore. One way of implementing the process of temporarily shutting in wells and continuing to inject gas into the shut-in well's wellbore may be a manual procedure in which engineers examine each of their wells tied to every compressor station and create tiers based on the well's gas/oil ratio (GOR). Wells with higher GOR may have less impact on oil production and more impact on removing gas when shut in. Engineers may then send the tier list to a control room to help determine which wells to temporarily shut in while continuing to inject gas into the shut-in wells' wellbores when third-party stations go down and cannot take any more gas. This list has to be continually updated and maintained as time goes on. As can be seen, such manual process may be inefficient.

The embodiments disclosed herein may handle excess gas by utilizing an information system to predict the gas excess and shut down wells temporarily while continuing to inject gas into the shut-in well's wellbore, which is referred as Closed Loop Gas Capture (CLGC) Lite in this disclosure. The CLGC Lite process may be used during a market upset when third-party sales stations go down and cannot take any more gas and it is desired to prevent flaring at the well facilities.

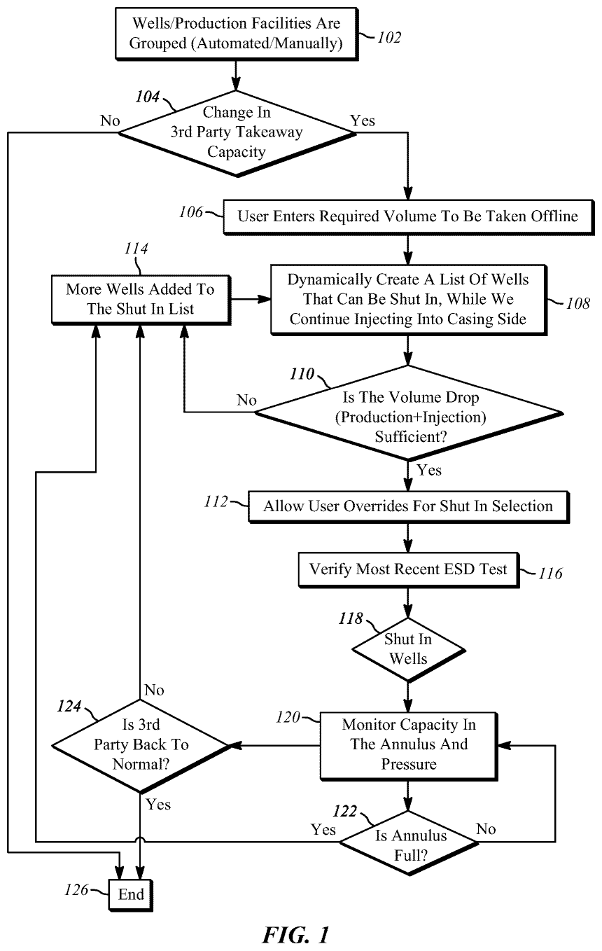

FIG. 1 illustrates a flow diagram 100 for hydrocarbon well management, in accordance with some embodiments of the present disclosure. At step 102, the wells or production facilities may be grouped. The grouping may be completed automatically or manually. At step 104, the system may determine whether there is a change in third-party takeaway capacity. If there is a change, an anticipation of excess gas may be determined and at step 106, a user (e.g., a controller) may enter required volume to be taken offline into the information system. In particular embodiments, the required volume may indicate the amount of excess gas/hour. If there is no change, the process may end at step 126.

At step 108, the information system may dynamically create a list of wells that can be shut in, while responsible parties continue injecting into casing side. In particular embodiments, the information system may check the gas/oil ratio (GOR) of a collection of wells and determine the most efficient group of wells to shut down to handle the excess. The information system may further select the wells with the highest gas/oil ratios. The information system may additionally select a group of wells of which the combined hourly gas production is equal to or slightly higher than the anticipated excess gas/hour.

At step 110, the information system may determine whether the volume drop (production plus injection) is sufficient. In particular embodiments, a controller may approve the system's decision or make a modification to the system's well selection before approving. If the volume drop is sufficient, the information system may allow user overrides for shut in selection at step 112. If the volume drop is not sufficient, more wells may be added to the shut in list at step 114.

At step 116, the user may verify most recent emergency-shutdown (ESD) test. At step 118, the user may shut in the selected wells temporarily. At step 120, the information system may monitor capacity in the annulus and pressure. At step 122, the information system may determine whether the annulus is full. If the annulus is full, more wells may be added to the shut in list at step 114. If the annulus is not full, the information system may return to step 118 to monitor capacity in the annulus and pressure.

At step 124, the information system may determine whether the third-party is back to normal. If the third-party is back to normal, the process may end at step 126. If the third-party is not back to normal, more wells may be added to the shut in list at step 114.

When the excess is resolved, the information system may show the shutdown wells with the lowest gas/oil ratios. Subsequently, a controller may select wells for reopening based on the system's recommendation.

In particular embodiments, the CLGC Lite process disclosed herein may be facilitated by a user interface (UI) designed to streamline the CLGC process by providing an interface for the control room to quickly decide on the wells to shut in and monitor them afterwards. The CLGC Lite UI may streamline the aforementioned manual process by providing an interface to display the compressor-well associations, retrieve the data required to calculate the well GORs, and generate real-time tier lists for these wells. This UI may be used by the control room to monitor and by the production engineers and field personnel to maintain.

During a market upset, the control room may select how much gas they would like to temporarily take off a hydrocarbon system based on the conditions in the field. Then the UI may highlight the wells that can be shut in with the least impact to oil production and the most impact to cutting gas. Using the annular volume and injection rates, the UI may calculate each well's wellbore injection gas capacity and the amount of time it would take to fill up, providing critical information on the amount of time one can buy during the market upset and to the limits to prevent injecting into each well's formation.

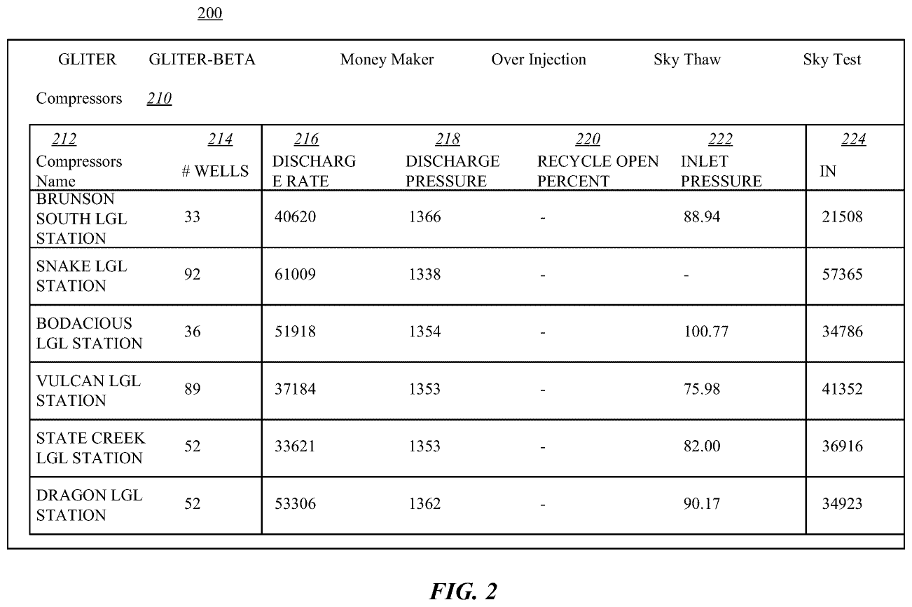

In particular embodiments, the UI may comprise a compressor summary page. FIG. 2 illustrates a compressor summary page 200, in accordance with some embodiments of the present disclosure. The compressor summary page 200 may provide a list of all compressors 210 available along with some real-time cygnet data metrics for each compressor 210. Each compressor 210 may also have an association of wells tied to it, and the allocated data metrics for the wells may be displayed. In particular embodiments, for each compressor 210, the compressor summary page 200 may display values associated with the compressor 210, including one or more of a compressor name 212 (i.e., name of the compressor station), a number of wells 214 currently associated to the compressor station 210, a current compressor discharge rate (mcf/day) 216 at the compressor, a current compressor discharge pressure (psi) 218 at the compressor 210, a current compressor recycle valve's open percent (%) 220, a current compressor station inlet pressure (psi) 222, a total injection gas (mcf/day) 224 across all the wells associated with the compressor from yesterday, a total injected and produced gas (mcf/day) across all the wells associated with the compressor from yesterday, a total produced oil (mcf/day) across all the wells associated with the compressor from yesterday, a number of wells that have been shut in for at least 3 days, or a number of wells that are currently shut int. In particular embodiments, the current compressor station inlet pressure 222 may be the value to monitor. When markets go down and gas gets backed up, the current compressor station inlet pressure 222 may rise.

The compressor-well associations provided in the compressor summary page 200 may be limited in the number of associations available. In addition, users may want the flexibility to take a subgroup of wells of their choice to perform calculations on temporarily injected gas into shut-in wells. To address these issues, the UI may display a subtab for custom groups within the compressor summary page 200. The subtab for custom groups may allow users to create their own separate groupings of wells to perform calculations on temporarily injected gas into shut-in wells. These groups may be not actual compressor-well associations but instead flexible, custom-made groups that provide a sandbox to simulate situations. The values for each compressor in the subtab for custom groups may be similar to the values for each compressor in the compressor summary page but without the compressor real-time values.

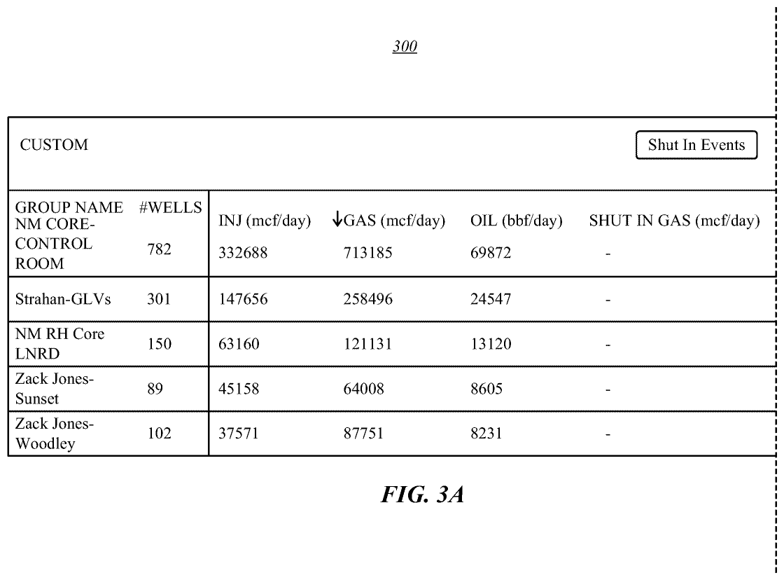

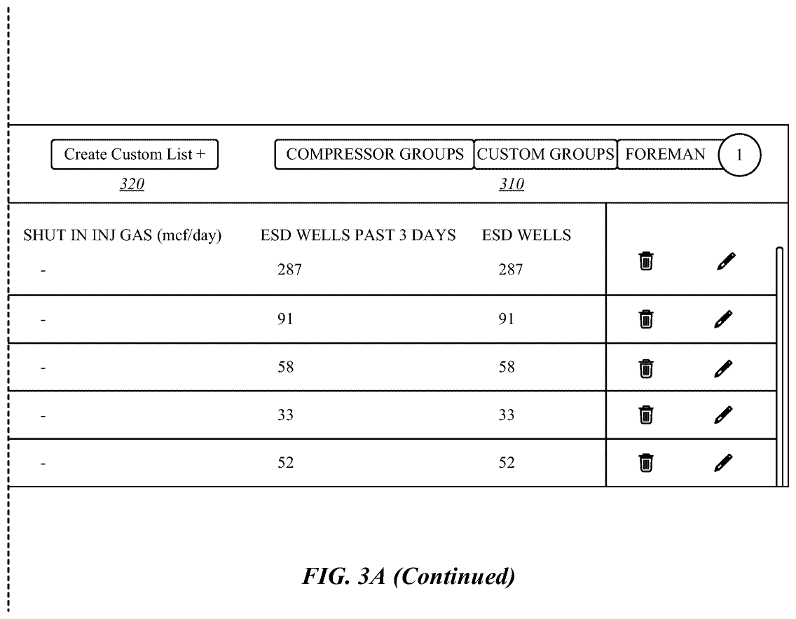

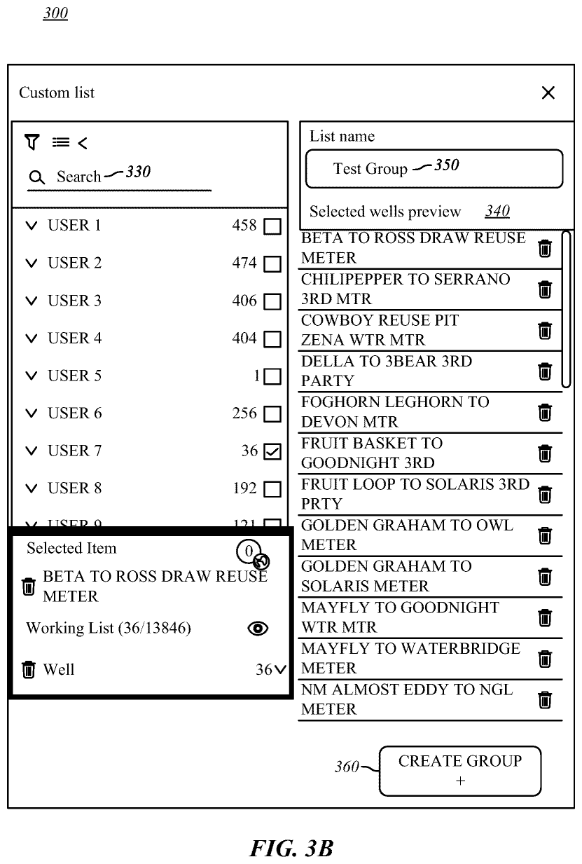

FIGS. 3A-3B illustrate a process 300 to use custom groups, in accordance with some embodiments of the present disclosure. To use custom groups, a user may click on “custom groups 310” while in the compressor summary page 200. The user may then click on “create custom list 320”. The user may then use the well search tree 330 to add wells to the working list. When using the well search tree 330, the user may create filters to narrow the well search tree 330 down to a more manageable list. Clicking the checkbox or shift clicking wells will add them to the list. The user may also delete wells in the “selected wells preview 340” list to remove them from the group. The user may then add a name 350 for the group and click on “create group 360.” Once the custom group is created, the user may delete the group completely or edit the group to add/remove wells from it.

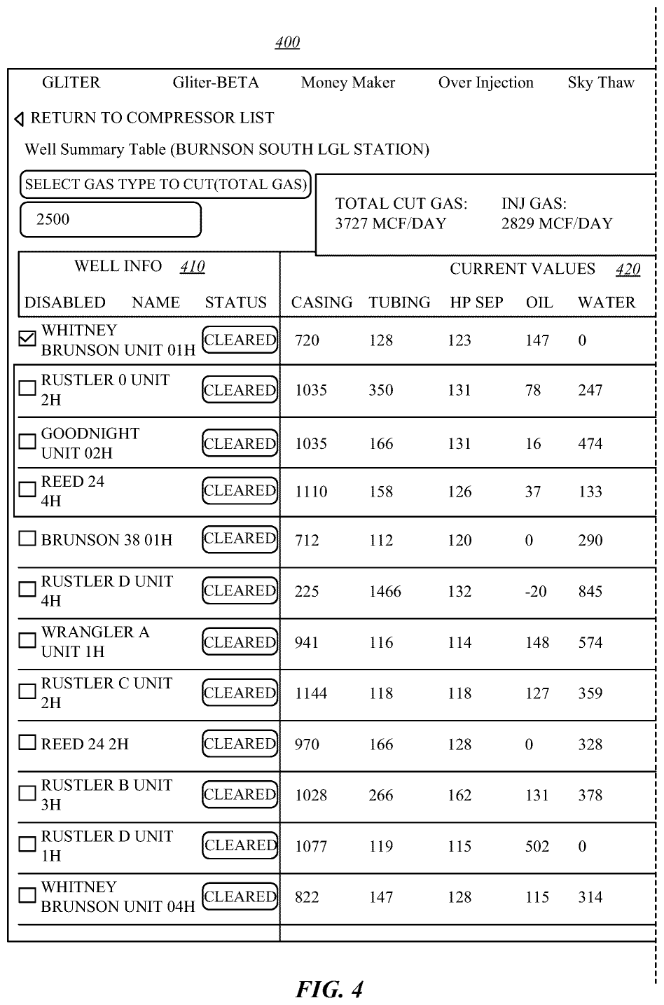

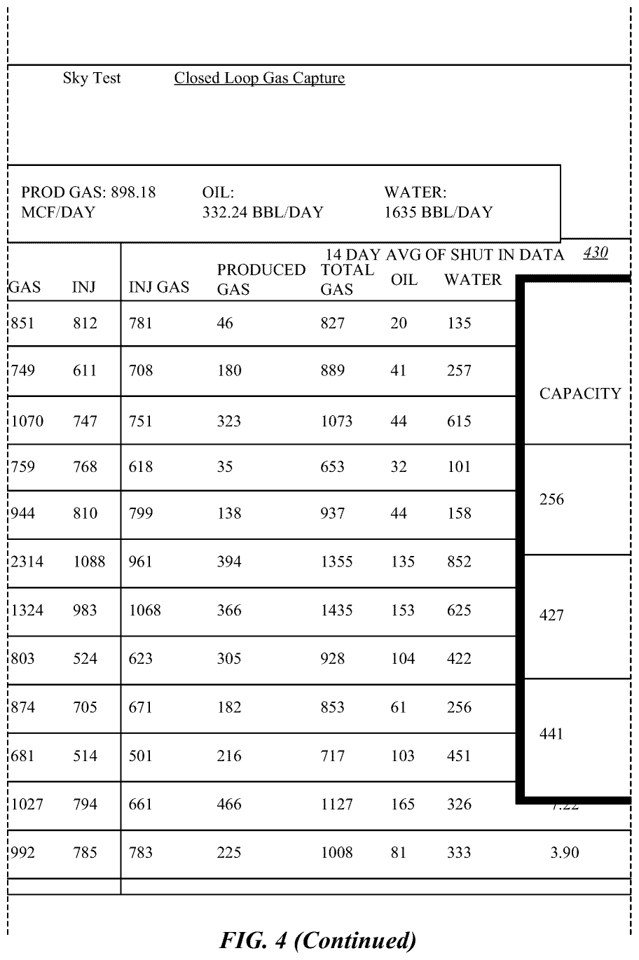

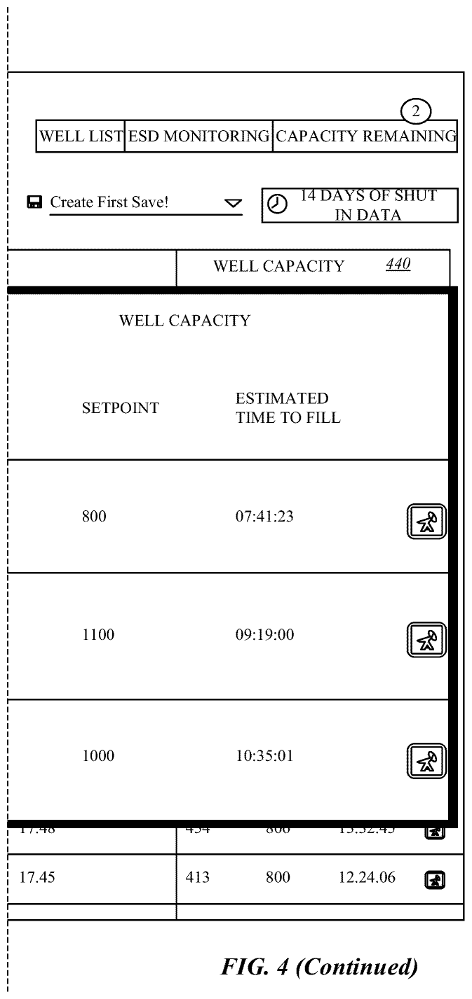

In particular embodiments, the UI may display a well summary table. FIG. 4 illustrates a well summary table 400, in accordance with some embodiments of the present disclosure. The well summary table 400 may provide a detailed view of all the wells associated with a compressor station. A user may can get to the well summary table 400 by clicking on any compressor or custom group while on the compressor summary page 200 or custom groups page. The column values in the well summary table 400 may include the following groups: well information 410, current values 420, X-day average of shut-in data 430, well capacity 440, and ESD information (not shown). Tables 1A-1C below list the detailed factors of each of these groups.

TABLE 1A
Factors of well information and current values.

| WELL INFO | | | | CURRENT VALUES | | | |
|---|---|---|---|---|---|---|---|
| UNLATCH | NAME | FOREMAN | STATUS | OIL | WATER | GAS | INJ |
| | | ROUTE | | (bbl/day) | (bbl/day) | (mcf/day) | (mcf/day) |

TABLE 1B
Factors of 14 days non-ESD production average.
14 DAYS NON-ESD PRODUCTION AVERAGE

| | | | | | | | | |
|---|---|---|---|---|---|---|---|---|
| INJ GAS | PRODUCED | TOTAL | OIL | WATER | NET | WOR | NET | ESD |
| (mcf/day) | GAS | GAS | (bbl/day) | (bbl/day) | PROD | (bbl/day) | TOTAL | [symbol] |
| | (mcf/day) | (mcf/day) | | | GOR | | GOR | |
| | | | | | (mcf/day) | | (mcf/day) | |

TABLE 1C
Factors of well capacity and ESD information.

| WELL CAPACITY | | | ESD INFO | | | |
|---|---|---|---|---|---|---|
| CAPACITY | SETPOINT | ESTIMATED | CAPACITY | SETPOINT | INJECTION | TIME TO |
| (mcf) | (mcf/day) | TIME TO | REMAINING | BEFORE | SHUTOFF | FILL |
| | | FILL | (mcf) | ESD | TS | (HH:MM:SS) |
| | | (HH:MM:SS) | | | | |

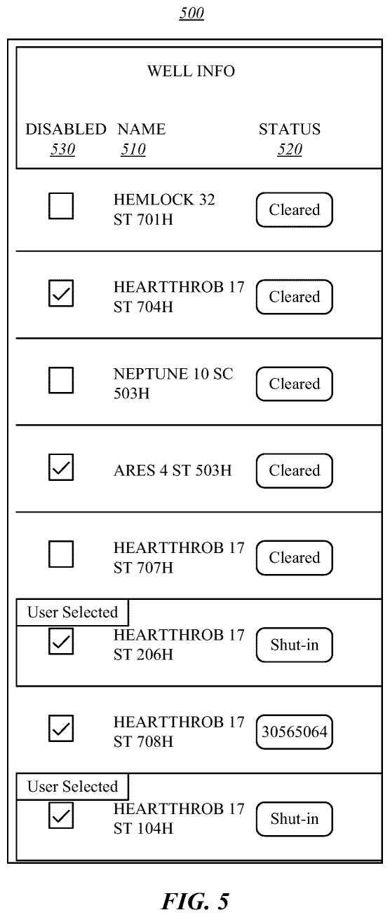

FIG. 5 illustrates well information 500, in accordance with some embodiments of the present disclosure. The well information 500 may show some basic metadata information about a well such as its name 510 and emergency shutdown (ESD) status 520. It may also provide a user checkbox to enable or disable 530 a well from the calculations on anticipating the excess and shutting down wells temporarily while continuing to inject gas into the shut-in well's wellbore. The checkbox for emergently shutdown wells may be automatically checked. Wells with invalid/zero setpoint values may also be excluded. ESD status 520 of “cleared” means that the well is not shut in. ESD status 520 that is not “cleared” means that the well is currently shut in. Well highlighted with the text “user selected” 540 means that the well was shut in manually by the control through the UI.

Current values 420 of the well summary table 400 may display the real-time cygnet readings for every well. These values may be displayed to view the current health of a well. As an example and not by way of limitation, the values may include casing pressure in PSI, tubing pressure in PSI, high separator pressure in PSI, total oil production yesterday in bbl/day, total water production yesterday in bbl/day, total produced gas production and injected gas yesterday in mcf/day, and total injected gas yesterday in mcf/day.

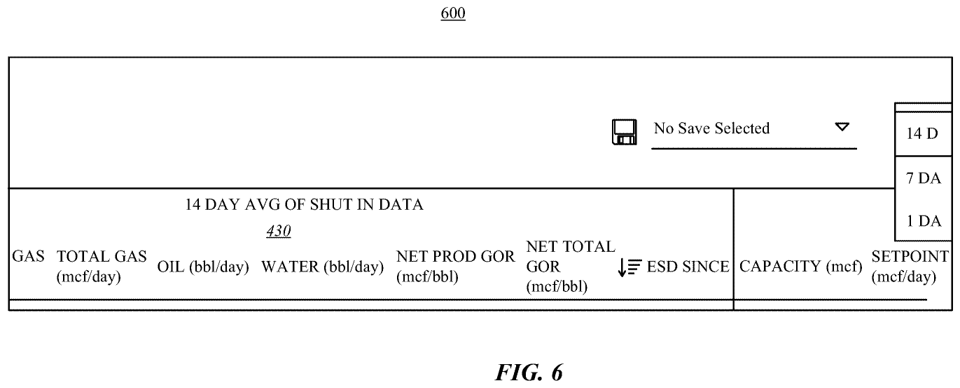

The X-day average of shut-in data 430 may display the projected amount of oil, water, or gas that will be shut in based on non-ESD'd allocated data. FIG. 6 illustrates a display 600 of the X-day average of shut-in data 430, in accordance with some embodiments of the present disclosure. Users may filter the shut-in data by 14-day average, 7-day average, or one day. As an example and not by way of limitation, the values may include total injected gas projected to be shut-in in mcf/day, total produced gas projected to be shut-in in mcf/day, total injected gas and produced gas projected to be shut-in in mcf/day, total oil projected to be shut-in in bbl/day, total water projected to be shut-in in bbl/day, net production GOR which is projected GOR by dividing produced gas with a multiplication of oil amount and the well's oil net revenue interest (NRI), net total GOR which is projected gas/oil ratio by dividing total gas with a multiplication of oil amount and well's oil NRI, and last date when the well had a day with zero hours of allocated downtime hours (empty if the well's ESD status is “cleared”).

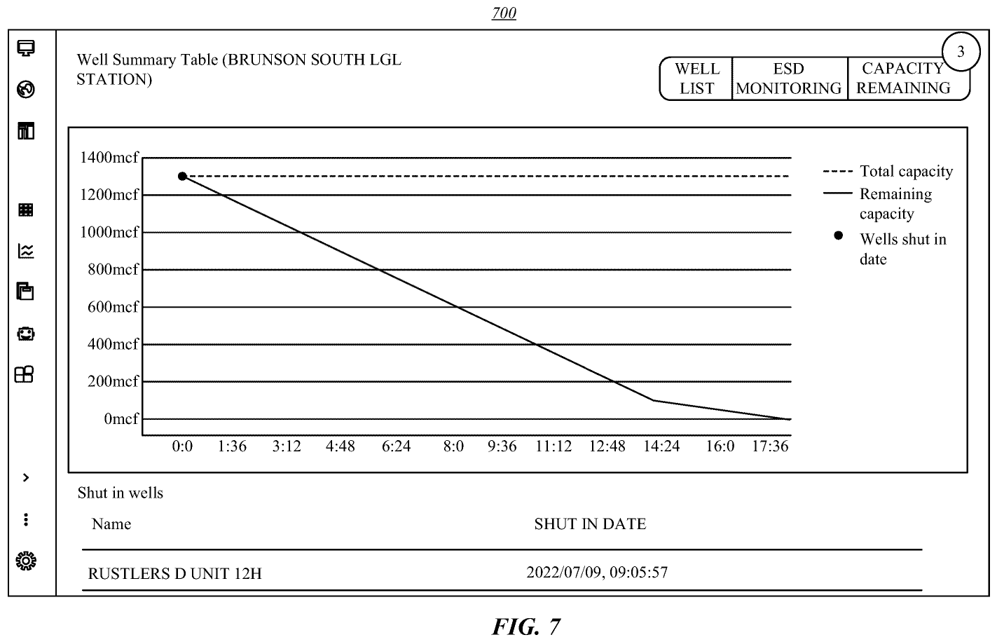

FIG. 7 illustrates a display 700 of the well capacity 440, in accordance with some embodiments of the present disclosure. The well capacity 440 may display the information regarding the gas injection capacity of the wellbore, the well's current setpoint, and the estimated time it will take for the wellbore to be filled using the current well injection setpoint. This data is valuable because one wants to ensure that they are not injecting into the formation of the well. As an example and not by way of limitation, the values may include capacity of the wellbore to take in gas injection in mcf, current setpoint of the well in mcf/day, the estimated time that it will take using the current setpoint before the well's capacity is filled up.

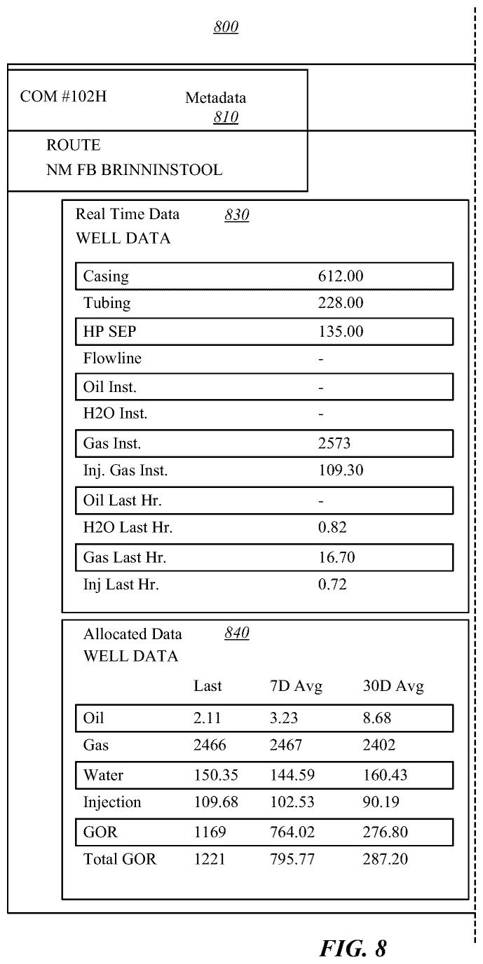

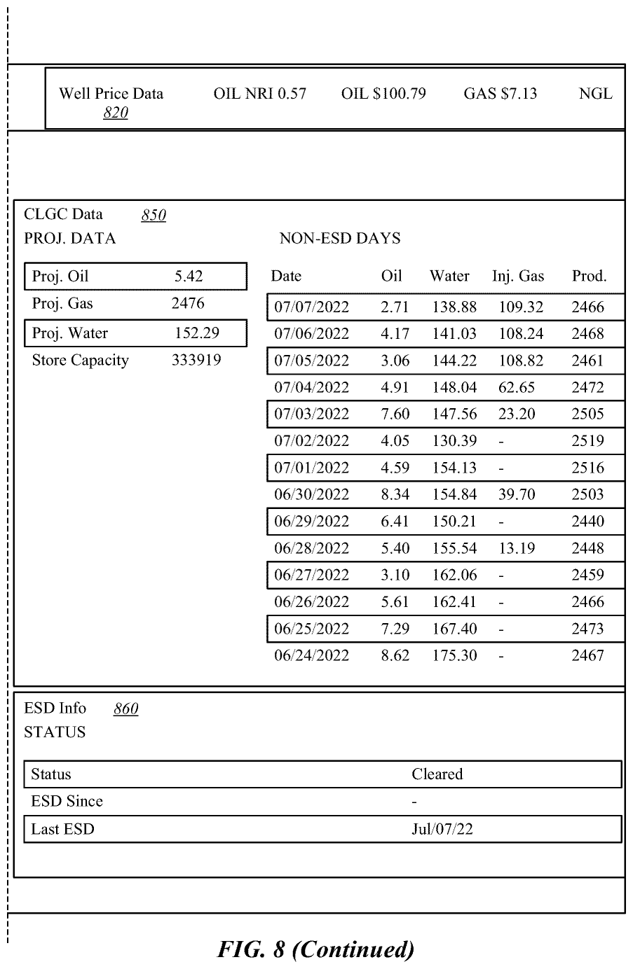

Well details may include an even more in-depth view of a well's metadata. FIG. 8 illustrates a display 800 of well details, in accordance with some embodiments of the present disclosure. The display 800 may include information such as metadata 810, price data 820, wellbore schematic, real time data 830, allocated data 840, CLGC data 850, and ESD information 860. Metadata may display the well's division, foreman, route, and name. Wellbore schematic may display a visual of the wellbore and the amount of oil/water/gas being produced. Price data may display the well's current oil/gas/NGL prices and the oil NRI used in the GOR calculations. Real-time data may display some of the well's real-time values like oil/water/gas production and pressures. Allocated data may display the current, 7-day, and 30-day averages of oil, gas, water, injection, or GOR values. CLGC data may display the past 14 days of data for a well in which there were no downtime hours during that allocated day. These values are the ones used to display the “X-day average of shut-in data” on the well summary table. ESD information may display the current ESD status, and when the well was last emergently shut down.

In particular embodiments, the information system may perform capacity calculations. Calculating the injected gas capacity in the wellbore of a well may be important for the following reasons. First, capacity calculations may provide a time estimate on how long it will take for the wellbore to be filled with injected gas. In addition, capacity calculations may provide a projected limit of gas to inject before responsible parties start injecting into the formation. In particular embodiments, the formula used to calculate the gas injection capacity of the wellbore may be: Capacity in mcf=(Volume of Wellbore*Real Time Injection Pressure*Well Head Surface Temperature)/(Casing Pressure*Real Time Gas Temperature)/1000.

In particular embodiments, the information system may perform non-ESD data calculations. To determine the projected amount of gas that will be shut in when a well with emergency shut down (ESD) and continued to have gas injected into, the information system may use the well's allocated production values to interpolate what the projected production would be. Using the allocated production as is may have some issues. Using the most recent day's allocated production values would be too small of a sample size to interpolate projected production effectively while using too many past allocated production values might include days in which a well was shut in, causing the projected production to decrease. These issues may be resolved by cleaning up the allocated data to only use days in which the allocated downtime hours value was 0. This means that a well was not shut in and producing the entire day without fail, allowing for getting a more accurate depiction of what the projected production of each well can be. Users may be also given the ability to select which average time frame they would like to view the well's projected production at, e.g., 14-day, 7-day, or 1-day. In particular embodiments, the values of the past 14 days of non-ESD data can be found in the well-details popup of the user interface.

In particular embodiments, the control room input may allow for the streamlined version of temporarily shutting in wells and continuing to inject gas into the shut-in well's wellbore with manual determination of which wells to shut in. During a market upset, the control room may communicate with all markets, and they may determine how much gas they will need to remove from the hydrocarbon system.

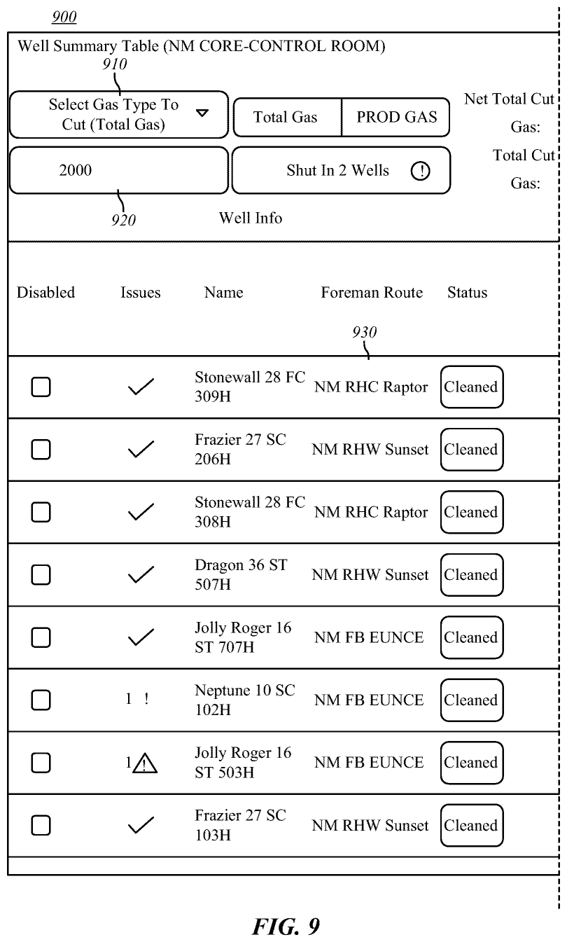

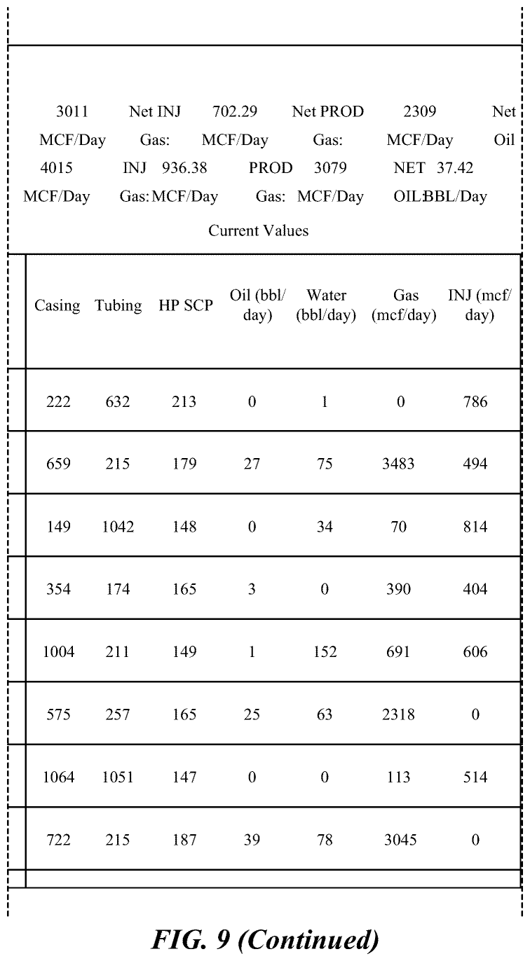

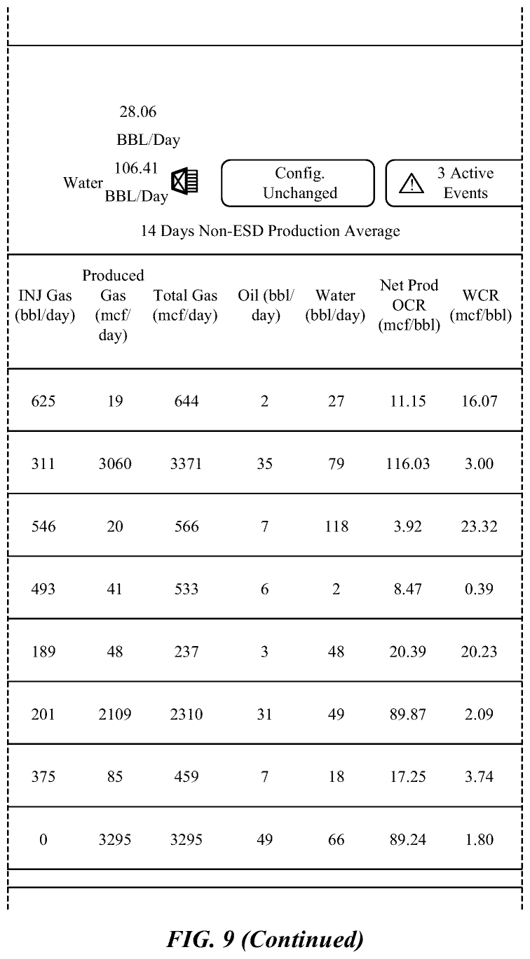

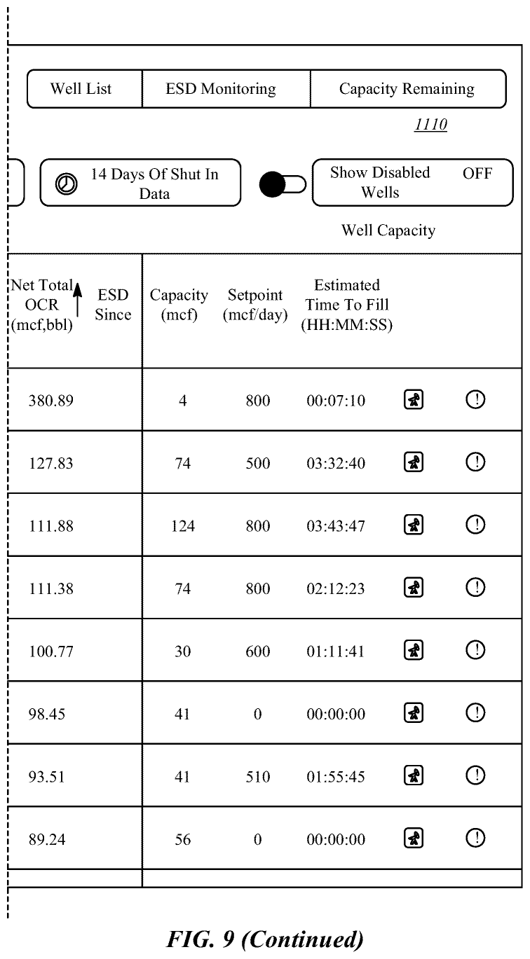

FIG. 9 illustrates a control room input piece 900, in accordance with some embodiments of the present disclosure. There may be a plurality of options for the amount of gas to cut. One option may be total gas, which is the total amount of gas to cut (including injection and production) in. Another option may be produced gas, which is the total amount of produced gas to cut in mcf/day. Another option may be injected gas, which is the total amount of injected gas to cut in mcf/day. After selecting 910 the type of gas to cut, the user may then input 920 a gas rate to remove from the hydrocarbon system.

In particular embodiments, the wells in the calculation of the amount of gas to cut may be sorted by net total GOR. Wells available for the calculation may be selected and their injected gas, produced gas, or total gas (depending on which amount of gas type was selected) may be subtracted from the input gas rate to remove until no more wells are needed. All the wells highlighted 930 may represent the wells that will be shut in that will remove the necessary amount of gas from the hydrocarbon system.

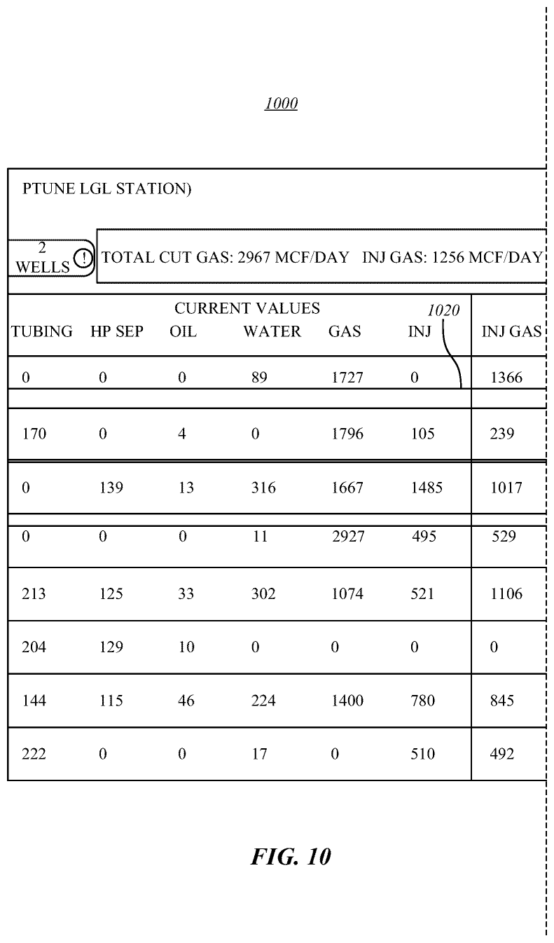

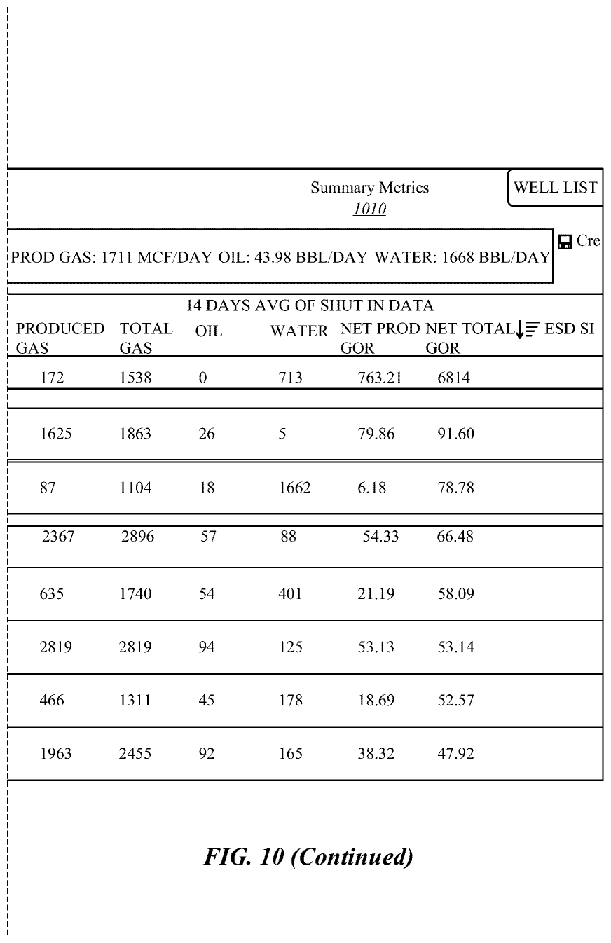

FIG. 10 illustrates a display 1000 of summary metrics 1010, in accordance with some embodiments of the present disclosure. In particular embodiments, there may be summary metrics 1010 showing the total production lost across gas, oil, or water if the highlighted wells 1020 are shut in. Once everything looks ready to go, the user can click the button to “shut in x wells” to start an event of temporarily shutting in wells and continuing to inject gas into the shut-in well's wellbore.

In particular embodiments, engineers and field personnel may be able to go into any custom group or compressor and make changes on the different user settings available in the well summary table. As an example and not by way of limitation, settings available to edit may include which wells to enable/disable, how many days of shut-in data to use, and which gas type to cut, etc. These changes may be available for other users to view and edit so that when the control room accesses the well summary table, all the engineers and field personnel's data has been included to provide all of their updated data.

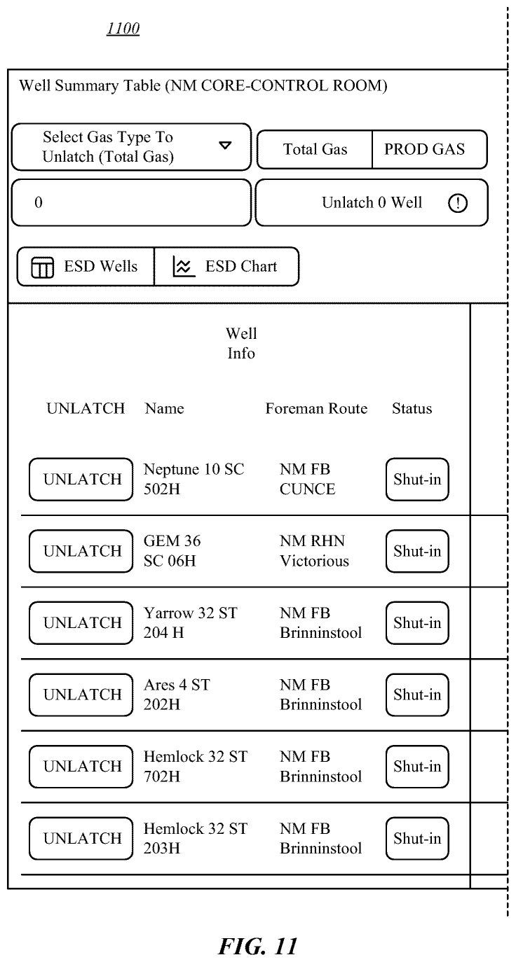

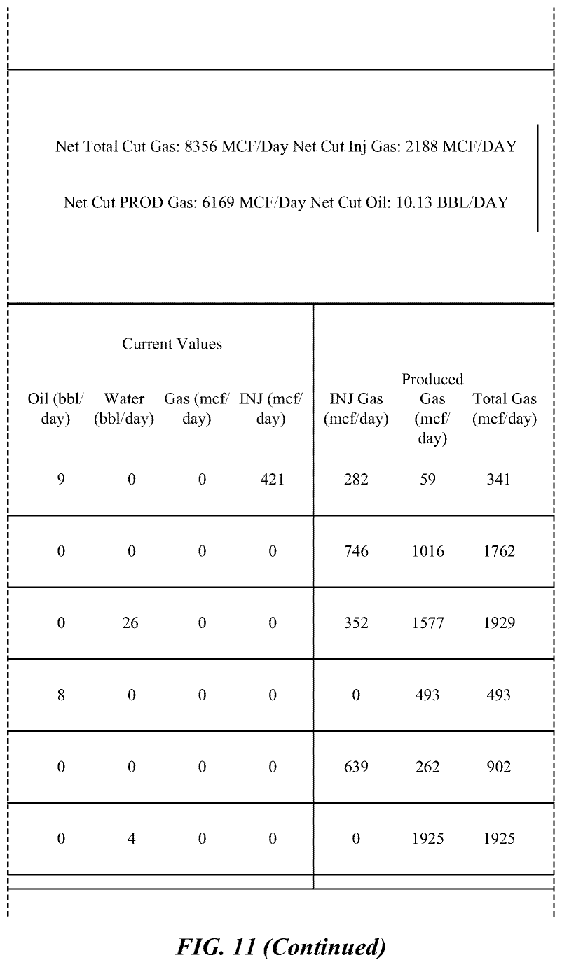

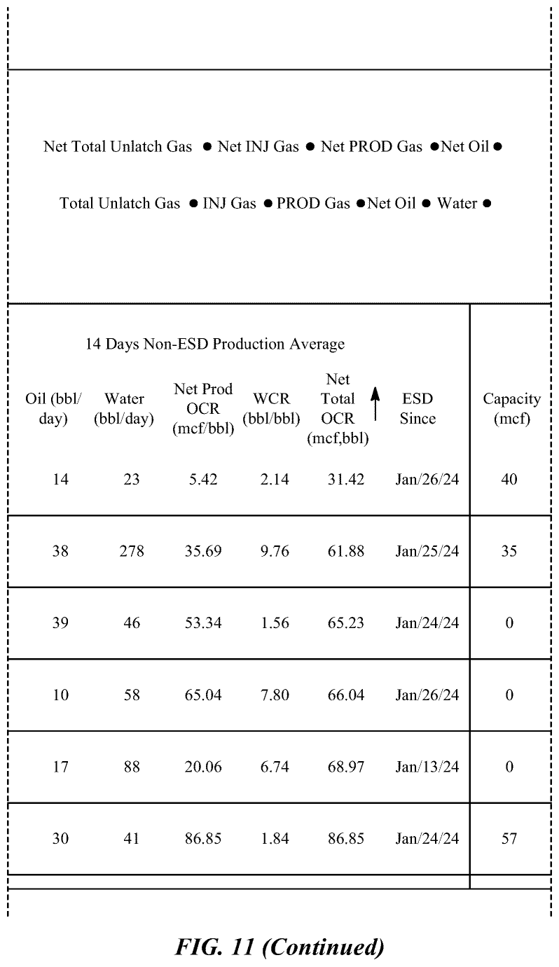

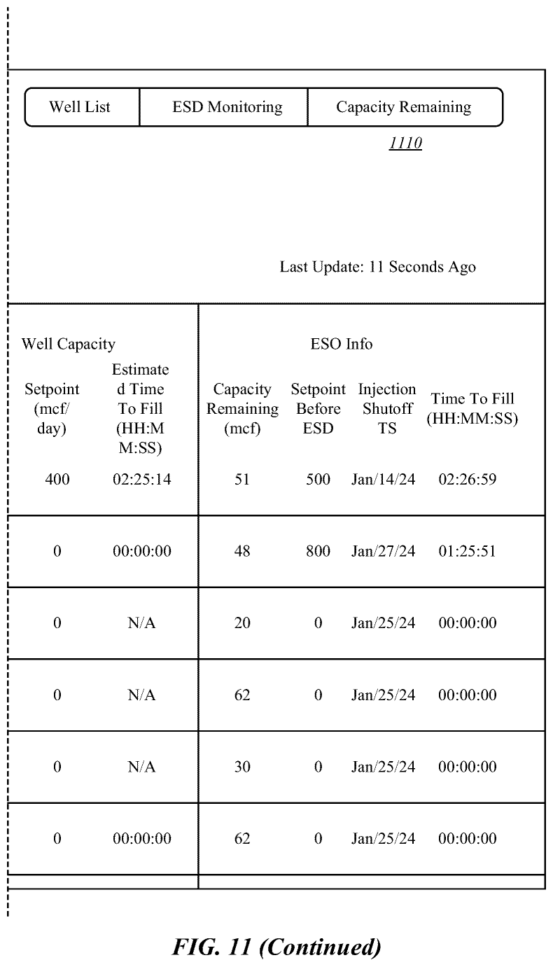

Once an event of temporarily shutting in wells and continuing to inject gas into the shut-in well's wellbore has been created, users may go to an ESD monitoring tab of the UI to view the event over time along with all the wells' relevant pressures. FIG. 11 illustrates an ESD monitoring page 1100, in accordance with some embodiments of the present disclosure.

When a well is emergently shut down and continues to have injection, the well's injection pressure may rise. When the injection gas pressure curve flattens out or exceeds the casing pressure, that means that no more gas can be injected into the wellbore or even the gas is being injected into the formation.

The monitoring page 1100 of the UI may allow the control room to view all wells involved in the process of temporarily shutting in wells and continuing to inject gas into the shut-in well's wellbore and ensure that the well is being properly injected into and if not, that the injection stops. The interactable piece of “Unlatch” may allow the user to manually open the well.

Each section in the ESD monitoring page 1100 may show an event in which wells were added to the event of temporarily shutting in wells and continuing to inject gas into the shut-in well's wellbore. Once an event of temporarily shutting in wells and continuing to inject gas into the shut-in well's wellbore is created for a compressor or custom group, users may continue to add amounts of gas to cut and shut in more wells. Each time a user adds shut-in wells, a new section may be added to the event.

Once an event of temporarily shutting in wells and continuing to inject gas into the shut-in well's wellbore has been created, users may go to the capacity remaining tab 1110 to view the projected amount of time that performing the process of temporarily shutting in wells and continuing to inject gas into the shut-in well's wellbore on the wells may buy along with the production losses that will occur due to the shut-in.

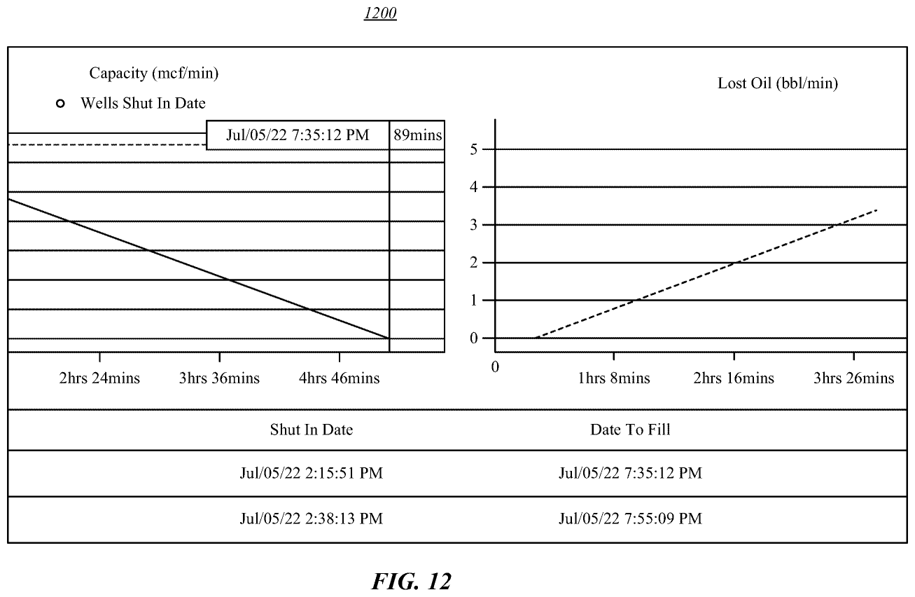

FIG. 12 illustrates a capacity remaining graph 1200, in accordance with some embodiments of the present disclosure. The capacity remaining graph 1200 may show several pieces of data. One piece of data may be over time: total capacity, which shows the amount of injected gas that is planned to be stored in the wellbore. As more wells are added to the event, the total capacity may increase. Another piece of data may be over remaining capacity, which shows the amount of available capacity left to inject into all the well's wellbore. As more wells are added to the event, the remaining capacity may increase and have a steeper decreasing curve over time. Another piece of data may be over wells shut-in date, which shows dots that represent the time that the well was added into the shut-in event. Another piece of data may be over lost oil, which shows the amount of lost oil production over time. Given that the wells are shut in during the entire event, the lost oil production may continue to increase at the same rate. As more wells are added, the lost oil production rate may increase. Another piece of data may be over current time in event, which may include a line that documents how far the event is currently at. Another piece of data may be in well filled data. Hovering over the wells that are shut in may display the projected time that the wellbore capacity of injected gas will reach its maximum capacity.

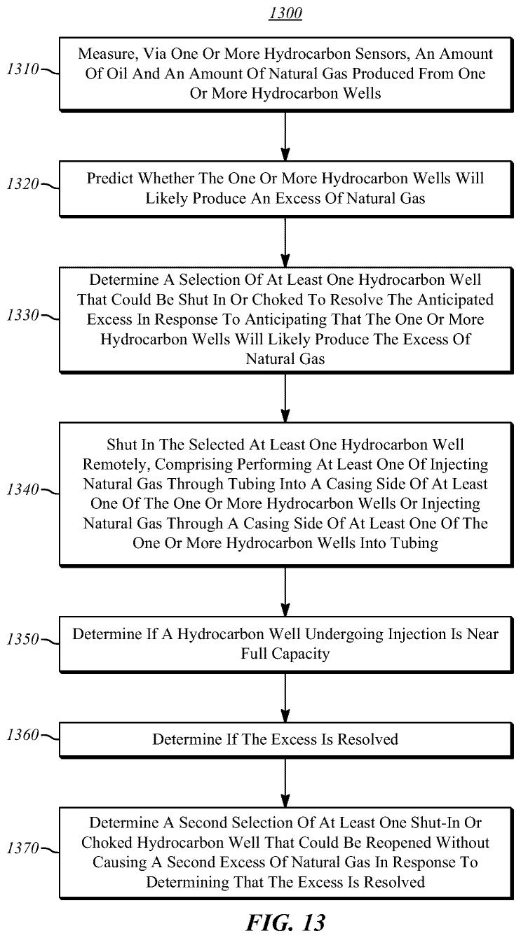

FIG. 13 illustrates a method 1300 for managing hydrocarbon wells, in accordance with some embodiments of the present disclosure. The method may begin at step 1310, where the information handling system may measure, via one or more hydrocarbon sensors, an amount of oil and an amount of natural gas produced from one or more hydrocarbon wells. At step 1320, the information handling system may predict whether the one or more hydrocarbon wells will likely produce an excess of natural gas. At step 1330, the information handling system may determine a selection of at least one hydrocarbon well that could be shut in or choked to resolve the anticipated excess in response to anticipating that the one or more hydrocarbon wells will likely produce the excess of natural gas. At step 1340, the information handling system may shut in the selected at least one hydrocarbon well remotely, comprising performing at least one of injecting natural gas through tubing into a casing side of at least one of the one or more hydrocarbon wells or injecting natural gas through a casing side of at least one of the one or more hydrocarbon wells into tubing. At step 1350, the information handling system may determine if a hydrocarbon well undergoing injection is near full capacity. At step 1360, the information handling system may determine if the excess is resolved. At step 1370, the information handling system may determine a second selection of at least one shut-in or choked hydrocarbon well that could be reopened without causing a second excess of natural gas in response to determining that the excess is resolved. Particular embodiments may repeat one or more steps of the method of FIG. 13, where appropriate. Although this disclosure describes and illustrates particular steps of the method of FIG. 13 as occurring in a particular order, this disclosure contemplates any suitable steps of the method of FIG. 13 occurring in any suitable order. Moreover, although this disclosure describes and illustrates an example method for managing hydrocarbon wells including the particular steps of the method of FIG. 13, this disclosure contemplates any suitable method for managing hydrocarbon wells including any suitable steps, which may include all, some, or none of the steps of the method of FIG. 13, where appropriate. Furthermore, although this disclosure describes and illustrates particular components, devices, or systems carrying out particular steps of the method of FIG. 13, this disclosure contemplates any suitable combination of any suitable components, devices, or systems carrying out any suitable steps of the method of FIG. 13.

The particular embodiments disclosed above are illustrative only, as the present invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular illustrative embodiments disclosed above may be altered or modified and all such variations are considered within the scope and spirit of the present invention. Also, the terms in the claims have their plain, ordinary meaning unless otherwise explicitly and clearly defined by the patentee. The indefinite articles “a” or “an,” as used in the claims, are each defined herein to mean one or more than one of the element that it introduces.

A number of examples have been described. Nevertheless, it will be understood that various modifications can be made. Accordingly, other implementations are within the scope of the following claims.

What is claimed is:

1. A system for managing the production of oil and gas from a plurality of hydrocarbon wells, the system comprising:
one or more hydrocarbon sensors coupled to one or more hydrocarbon wells, wherein the one or more hydrocarbon sensors are operable to measure an amount of oil and an amount of natural gas produced from the one or more hydrocarbon wells; and
an information handling system in electronic communication with the one or more hydrocarbon sensors, the information handling system comprising:
a processor, and
a non-transitory computer readable medium for storing one or more instructions that, when executed, causes the processor to:
predict whether the one or more hydrocarbon wells will likely produce an excess of natural gas; and
in response to anticipating that the one or more hydrocarbon wells will likely produce the excess of natural gas, determine a selection of at least one hydrocarbon well that could be shut in or choked to eliminate the anticipated excess of natural gas being produced.

2. The system of claim 1, wherein the selection is determined at least in part to minimize a reduction of oil produced as a result of shutting in or choking at least one hydrocarbon well.

3. The system of claim 2, wherein at least one of:
each of the selected at least one hydrocarbon wells has a higher gas/oil ratio than each of the one or more hydrocarbon wells that were not selected;
each of the selected at least one hydrocarbon wells is nearer a sales point than each of the one or more hydrocarbon wells that were not selected; or
each of the selected at least one hydrocarbon wells is equipped with compression equipment.

4. The system of claim 1, wherein the instructions stored in the non-transitory computer readable medium further cause the processor to:
determine if the excess of natural gas being produced has been eliminated; and
in response to determining that the excess of natural gas being produced has been eliminated, determine a second selection of at least one shut-in or choked hydrocarbon well that could be reopened without causing a second excess of natural gas.

5. The system of claim 4, wherein the second selection is determined at least in part to maximize the amount of oil produced by the one or more hydrocarbon wells without causing the second excess of natural gas.

6. The system of claim 1, wherein the instructions stored in the non-transitory computer readable medium further cause the processor to determine an amount of natural gas each hydrocarbon well can temporarily hold based at least in part on one or more of tubing dimensions, casing dimensions, injection rates, and well pressure.

7. The system of claim 6, wherein each of the shut-in or choked hydrocarbon wells selected to be reopened has a lower gas/oil ratio than each of the shut-in or choked hydrocarbon wells that were not selected to be reopened.

8. The system of claim 1, wherein the instructions stored in the non-transitory computer readable medium further cause the processor to display a user interface, wherein the user interface is operable to allow a user to modify the selection.

9. The system of claim 1, wherein the instructions stored in the non-transitory computer readable medium further cause the processor to receive production data from the one or more hydrocarbon sensors and determine a gas/oil ratio of at least one of the one or more hydrocarbon wells based on the production data of the at least one hydrocarbon well on days that the at least one hydrocarbon well did not have downtime.

10. The system of claim 1, wherein the selection is determined based at least in part on one or more of gas/oil ratio, boosting status, auto-choke status, and whether a user has designated wells to be unaltered.

11. The system of claim 1, wherein the selection is updated at least daily.

12. The system of claim 1, further comprising a logic controller operable to shut in at least one hydrocarbon well, wherein the logic controller is in electronic communication with the information handling system, and wherein the instructions stored in the non-transitory computer readable medium further cause the processor to communicate with the logic controller and to thereby shut in the selected at least one hydrocarbon well.

13. The system of claim 12, further comprising:
at least one gas lift injection valve fluidly coupled to at least one of the one or more hydrocarbon wells, wherein the at least one gas lift injection valve is operable to perform at least one of:
injecting natural gas through tubing into a casing side of at least one of the one or more hydrocarbon wells; or
injecting natural gas through a casing side of at least one of the one or more hydrocarbon wells into tubing,
wherein the instructions stored in the non-transitory computer readable medium further cause the processor to determine if a hydrocarbon well undergoing injection is near full capacity.

14. A computer-implemented method for managing the production of oil and gas from a plurality of hydrocarbon wells, the computer-implemented method comprising:
measuring, via one or more hydrocarbon sensors, an amount of oil and an amount of natural gas produced from one or more hydrocarbon wells;
predicting whether the one or more hydrocarbon wells will likely produce an excess of natural gas; and
in response to anticipating that the one or more hydrocarbon wells will likely produce the excess of natural gas, determining a selection of at least one hydrocarbon well that could be shut in or choked to eliminate the anticipated excess of natural gas.

15. The computer-implemented method of claim 14, wherein the selection is determined at least in part to minimize a reduction of oil produced as a result of shutting in or choking at least one hydrocarbon well, wherein the at least one hydrocarbon well was shut in or choked to eliminate the anticipated excess of natural gas.

16. The computer-implemented method of claim 15, wherein at least one of:
each of the selected at least one hydrocarbon wells has a higher gas/oil ratio than each of the one or more hydrocarbon wells that were not selected;
Each of the selected at least one hydrocarbon wells is nearer a sales point than each of the one or more hydrocarbon wells that were not selected; or
each of the selected at least one hydrocarbon wells is equipped with compression equipment.

17. The computer-implemented method of claim 14, further comprising:
determining if the excess of natural gas has been eliminated; and
in response to determining that the excess of natural gas has been eliminated, determining a second selection of at least one shut-in or choked hydrocarbon well that could be reopened without causing a second excess of natural gas.

18. The computer-implemented method of claim 17, wherein the second selection is determined at least in part to maximize the amount of oil produced by the one or more hydrocarbon wells without causing the second excess of natural gas.

19. The computer-implemented method of claim 14, further comprising determining an amount of natural gas each hydrocarbon well can temporarily hold based at least in part on one or more of tubing dimensions, casing dimensions, injection rates, and well pressure.

20. The computer-implemented method of claim 19, wherein each of the shut-in or choked hydrocarbon wells selected to be reopened has a lower gas/oil ratio than each of the shut-in or choked hydrocarbon wells that were not selected to be reopened.

21. The computer-implemented method of claim 14, further comprising displaying a user interface, wherein the user interface is operable to allow a user to modify the selection.

22. The computer-implemented method of claim 14, further comprising:
receiving production data from the one or more hydrocarbon sensors; and
determining a gas/oil ratio of at least one of the one or more hydrocarbon wells based on the production data of the at least one hydrocarbon well on days that the at least one hydrocarbon well did not have downtime.

23. The computer-implemented method of claim 14, wherein the selection is determined based at least in part on one or more of gas/oil ratio, boosting status, auto-choke status, and whether a user has designated wells to be unaltered.

24. The computer-implemented method of claim 14, wherein the selection is updated at least daily.

25. The computer-implemented method of claim 14, further comprising shutting in the selected at least one hydrocarbon well remotely.

26. The computer-implemented method of claim 25, further comprising:
performing at least one of:
injecting natural gas through tubing into a casing side of at least one of the one or more hydrocarbon wells; or
injecting natural gas through a casing side of at least one of the one or more hydrocarbon wells into tubing; and
determining if a hydrocarbon well undergoing injection is near full capacity.
